(19) United States
(12) Patent Application Publication
(10) Pub. No.: US 2026/0145247 A1
(43) Pub. Date: May 28, 2026

(54) COATED CUTTING TOOL

(71) Applicant: AB SANDVIK COROMANT, Sandviken (SE)

(72) Inventors: Linus VON FIEANDT, Sandviken (SE); Raluca MORJAN BRENNING, Sandviken (SE); Jan ENGQVIST, Sandviken (SE); Siamak SHOJA, Sandviken (SE)

(21) Appl. No.: 19/121,933

(22) PCT Filed: Sep. 29, 2023
(86) PCT No.: PCT/EP2023/077136

§ 371 Date: Apr. 17, 2025

(30) Foreign Application Priority Data
Oct. 21, 2022 (EP) 22203016.5

(51) Int. Cl. B23B 27/14; C23C 16/34; C23C 16/36; C23C 16/40

(52) U.S. Cl. CPC B23B 27/148; B23B 2228/105; C23C 16/34; C23C 16/36; C23C 16/403

(57) ABSTRACT

The present invention relates to a coated cutting tool including a substrate at least partially coated with a coating. The coating includes a layer of Ti(C,N), a layer of α-Al₂O₃ and therebetween a bonding layer. The Ti(C,N) layer has a thickness of 3-20 μm and includes an inner Ti(C,N) portion, T1, followed by an outer Ti(C,N) portion, T2, as seen in a direction from the substrate towards the outer surface of the tool. The thickness of the inner portion T1 is 2.5-15 μm and the thickness of the outer portion T2 is 0.5-5 μm. The average grain width of the Ti(C,N) grains in T1 and in T2 is smaller than 300 nm. The atomic ratio C/N in the inner Ti(C,N) portion, T1, is 1.50-1.60, and the atomic ratio C/N in the outer Ti(C,N) portion, T2, is 1.25-1.40.

### TECHNICAL FIELD

The present invention relates to a coated cutting tool comprising a substrate and a coating, wherein the coating is deposited by chemical vapor deposition (CVD) and comprises a Ti(C,N) layer and an α-Al₂O₃-layer.

### BACKGROUND

Coated cutting tools are well known in the metal cutting industry. CVD coated cutting tools and PVD coated cutting tools are the two most dominating types of coated cutting tools. Advantages with these coatings are high resistance to chemical and abrasive wear which are important to achieve long tool life of the coated cutting tool. CVD coatings comprising a layer of Ti(C,N) together with a layer of alumina are known to perform well in for example turning or milling of steel.

Recent studies have shown that the combination of a very fine grained Ti(C,N) layer and an Al₂O₃ layer sometimes leads to poor adhesion between the Ti(C,N) and the Al₂O₃. It is of interest to address this issue as a very fine grained Ti(C,N) has shown promising performance for cutting tools.

It is an object of the present invention to provide a coated cutting tool for metal cutting with a high adhesion between the Ti(C,N) and the Al₂O₃ layers of the coating. It is a further object to provide a coated cutting tool with high wear resistance, especially with high resistance to flaking during metal cutting. It is also an object of the present invention to provide a cutting tool with high resistance to crater wear in metal cutting in steel.

### DESCRIPTION OF THE INVENTION

At least one of the above-mentioned objects is achieved by a coated cutting tool according to claim 1. Preferred embodiments are disclosed in the dependent claims.

The present invention relates to a coated cutting tool comprising a substrate at least partially coated with a coating, wherein said coating comprising a layer of Ti(C,N), a layer of α-Al₂O₃ and therebetween a bonding layer. The Ti(C,N) layer with a thickness of 3-20 μm, preferably 5-15 μm, most preferably 6-10 μm, is composed of columnar grains, wherein the Ti(C,N) layer comprises an inner Ti(C,N) portion, T1, followed by an outer Ti(C,N) portion, T2, as seen in a direction from the substrate towards the outer surface of the tool. The thickness of the inner portion, T1, is 2.5-15 μm, preferably 3-10 μm, and the thickness of the outer portion T2 is 0.5-5 μm, preferably 0.5-3 μm, more preferably 0.5-2 μm. The grain width of the Ti(C,N) grains in the inner Ti(C,N) portion, T1, is smaller than 300 nm, preferably smaller than 200 nm, more preferably smaller than 100 nm and the grain width of the Ti(C,N) grains in the outer Ti(C,N) portion, T2, is smaller than 300 nm, preferably smaller than 200 nm. The atomic ratio C/N in inner Ti(C,N), T1, is 1.50-1.60, and the atomic ratio C/N in the outer Ti(C,N) portion, T2, is 1.25-1.40, preferably 1.27-1.36.

The Ti(C,N) portions T1 and T2 are defined by their atomic C/N ratio. A line scan in Electron Probe Microanalysis (EPMA) is used to identify the thicknesses of these portions based on their C/N ratio. The atomic C/N ratio is preferably approximately constant within the respective portion, i.e. the ratio can vary about ±2%.

It has surprisingly been found that a coated cutting tool comprising a columnar, fine grained Ti(C,N) layer that comprises two portions, one inner portion with a slightly higher carbon content than an outer portion, has shown an increased crater wear resistance and also an increased resistance against coating delamination.

In one embodiment of the present invention the average grain width of the Ti(C,N) grains in the inner Ti(C,N) portion, T1, is smaller than the average grain width of the Ti(C,N) in the outer Ti(C,N) portion, T2. An outer portion with a grain width larger than the inner portion is advantageous in that it contributes to the adhesion of a subsequent bonding layer.

In one embodiment of the present invention, the Ti(C,N) layer comprises an outer portion, T2, which is adjacent to the bonding layer, wherein the Ti(C,N) grains in the uppermost region of T2 have an average grain width of 90-250 nm, preferably 100-200 nm. The T2 portion can contribute to increased adhesion of the bonding layer and the subsequent α-Al₂O₃ layer. If the average grain width in the uppermost region of T2 is too large the adhesion is still high, but it was found that the TC(0012) of the subsequently deposited α-Al₂O₃ layer was reduced. If the average grain width in the uppermost region of T2 is too low the coating adhesion of subsequent layers might be reduced. The uppermost region of T2 is the region of T2 that is closest to the bonding layer. With the average grain width of the Ti(C,N) grains adjacent to the bonding layer is herein meant the average grain width of the Ti(C,N) grains as measured along a line about 300 nm from the bonding layer.

In one embodiment of the present invention the average grain width of the Ti(C,N) grains in the inner Ti(C,N) portion, T1, is <100 nm. Fine grained Ti(C,N) can be advantageous as a wear resistant layer, which could be due to its high amount of grain boundaries or due to a more smooth or even thickness of the layer. The portion of the TiCN layer that is fine grained should therefore be relatively thick.

In one embodiment of the present invention the average grain size D₄₂₂ of the inner Ti(C,N) portion, T1, of the Ti(C,N) layer is 25-50 nm, as measured with X-ray diffraction with CuKα radiation, the grain size D₄₂₂ is calculated from the full width at half maximum (FWHM) of the (422) peak according to Scherrer's equation:

$${D}_{422} = \frac{K λ}{{B}_{422} cos θ} \qquad ( 1 )$$

wherein D₄₂₂ is the average grain size of the Ti(C,N), K is the shape factor here set at 0.9, λ is the wavelength for the CuKα radiation here set at 1.5405 Å, B₄₂₂ is the FWHM value for the (422) reflection and θ is the Bragg angle.

It is difficult to study the average grain width of very fine grained Ti(C,N) since the orientation contrast difference of the grains and the recognition of grain boundaries in a polished cross section studied with for example SEM and EBSD can be very low. The person skilled in the art realizes that when the amount of signal in the analyses gets too low, the result can no longer be trusted. To study even more fine grained Ti(C,N), such as when the average grain width is smaller than 75 nm, we herein utilized XRD and the Scherrer's equation.

In one embodiment of the present invention, the thickness of the α-Al₂O₃ layer is 1-15 μm, preferably 3-9 μm.

The coated cutting tool of claim 1, wherein the α-Al₂O₃ layer exhibits a texture coefficient TC(hkl), as measured by X-ray diffraction using CuKα radiation and θ-2θ scan, defined according to Harris formula

$$TC ( hkl ) = {\frac{I ( hkl )}{{I}_{0} ( hk )} [ \frac{1}{n} {\sum }_{n = 1}^{n} \frac{I ( hkl )}{{I}_{0} ( hk )} ]}^{- 1} \qquad ( 2 )$$

where I(hkl) is the measured intensity (integrated area) of the (hkl) reflection, I₀(hkl) is the standard intensity according to ICDD's PDF-card No 00-010-0173, n=number of reflections, the reflections used are: (1 0 4), (1 1 0), (1 1 3), (0 2 4), (11 6), (2 1 4), (3 0 0) and (0 0 12), wherein the TC(0 0 12) is the largest texture coefficient. A high TC(0 0 12) has shown to contribute to a high crater wear resistance in steel metal cutting.

In one embodiment of the present invention the TC(0012) of the α-Al₂O₃ layer is >7.7, preferably >7.8.

In one embodiment of the present invention the α-Al₂O₃ layer comprises a portion A1 extending 1 μm from the bonding layer, wherein said portion A1 as measured with Electron Backscatter Diffraction (EBSD) on a cross section of said α-Al₂O₃ layer, wherein a surface normal of the α-Al₂O₃ layer is parallel to the surface normal of the substrate surface, said portion A1 exhibits an orientation wherein ≥70%, preferably ≥80%, more preferably ≥90%, most preferably ≥395%, of the analysed area has a <001> direction within 15 degrees from the surface normal of the α-Al₂O₃ layer.

In one embodiment of the present invention the Ti(C,N) layer, including the T1 portion and the T2 portion, exhibits a texture coefficient TC(hkl), as measured by X-ray diffraction using CuKα radiation and θ-2θ scan, defined according to Harris formula (2)
where I(hkl) is the measured intensity (integrated area) of the (hkl) reflection, I₀(hkl) is the standard intensity according to ICDD's PDF-card No 42-1489, n is the number of reflections, reflections used in the calculation are (1 1 1), (2 0 0), (2 2 0), (3 1 1), (3 3 1), (4 2 0) and (4 2 2), wherein TC(422)>3.

In one embodiment of the present invention the TC(422)+TC(311) of the Ti(C,N) layer is 5-6.

In one embodiment of the present invention the bonding layer comprises at least one compound selected from the group of titanium carboxide, titanium oxynitride and titanium carboxynitride. A bonding layer comprising titanium carboxide, titanium oxynitride or titanium carboxynitride is advantageous in that it can provide an epitaxial relation between the Ti(C,N) layer and the α-Al₂O₃ layer. The lowest part of the bonding layer is preferably a very nitrogen rich Ti(C,N) layer that preferably is deposited at about 1000° C. Preferably the total thickness of the bonding layer is 0.5-2 μm.

In one embodiment of the present invention the coating comprises an innermost layer of TiN, preferably with a thickness of 0.1-0.5 μm.

In one embodiment of the present invention the substrate of the coated cutting tool is selected from the group of cemented carbide and cermet.

### Definitions

The term “cutting tool” is herein intended to denote cutting tools suitable for metal cutting applications such as inserts. The application areas can for example be turning, milling or drilling in metals such as steel.

The cutting tool disclosed herein comprises a substrate and a coating. The coated cutting tool can be an insert comprising a rake face, a flank face and a cutting edge therebetween. The substrate, the coating and the layers thereof each have an outer surface. With surface normal or normal to the outer surface is intended a direction perpendicular to a surface plane of the outer surface, i.e in the preferential growth direction of the coating.

### Methods

### Coating Deposition

The coatings in the examples below were deposited in a radial Ionbond Bernex™ type CVD equipment 530 size capable of housing 10000 half-inch size cutting inserts.

C/N measurement with Electron Probe Microanalysis (EPMA)

In order to determine the atomic C/N ratio of the Ti(C,N) layer portions T1 and T2 elemental analysis of the coatings was performed by electron microprobe analysis using a JEOL electron microprobe JXA-8530F equipped with wavelength dispersive spectrometer (WDS). A Ti(C,N) reference sample was used for calibration with a composition of 10.22 wt % C, 10.68 wt % N, 78.86 wt % Ti and 0.24 wt % O. The analysis of each Ti(C,N) layer portion was conducted on a polished cross section of the coating of the rake face of the cutting tool. Titanium, carbon and nitrogen mapping was made over the whole layer thickness of the Ti(C,N) layer using 10 kV, 40 nA. The Ti, C and N content of the portion T1 and portion T2 of the Ti(C,N) layer was measured in at least different 5 positions at least 5 μm apart in the middle of the portion. The thicknesses of each portion T1 and T2 was identified via the line scan. The atomic C/N ratio is preferably approximately constant within the respective portion, i.e. the ratio can for example vary about ±2% within one portion.

Grain Size of Ti(C,N) with XRD and Scherrer

In order to investigate the average grain size of the Ti(C,N) grains having an average grain size smaller than about 75 nm, as can be found in embodiments of the present invention in the lower portion of the Ti(C,N) layer, portion T1, X-ray diffraction (XRD) was conducted on the flank face using a PANalytical CubiX3 diffractometer equipped with a PIXcel detector. Since layers above the Ti(C,N)-layer will affect the X-ray intensities entering the Ti(C,N)-layer and exiting the whole coating, corrections need to be made for these, taken into account the linear absorption coefficient for the respective compound in a layer. Alternatively layers above, for example the Ti(C,N) portion T2, can be removed by a method that does not substantially influence the XRD measurement results, e.g. grinding or laser ablation.

The coated cutting tool was mounted in a sample holder to ensure that the flank face of the samples was parallel to the reference surface of the sample holder and also that the flank face was at appropriate height. Cu-Kα radiation was used for the measurements, with a voltage of 45 kV and a current of 40 mA. Anti-scatter slit of ½ degree and divergence slit of ¼ degree were used. The diffracted intensity from the coated cutting tool was measured in the 2θ range 20° to 140°, i.e. over an incident angle θ range from 10 to 70°. The data analysis, including background fitting, Cu-Kα₂ stripping and profile fitting of the data, was done using PANalytical's X'Pert HighScore Plus software.

The integrated peak full width at half maximum for the profile fitted curve achieved from PANalytical's X'Pert HighScore Plus software was used to calculate the grain size of the layer according to the Scherrer equation (Eq1) (Birkholz, 2006).

The average grain size D₄₂₂ is then calculated from the full width at half maximum (FWHM) of the (422) peak according to Scherrer's equation:

$${D}_{422} = \frac{K λ}{{B}_{422} cos θ} \qquad ( 1 )$$

wherein D₄₂₂ is the mean grain size of the Ti(C,N), K is the shape factor here set at 0.9, λ is the wavelength for the CuKα₁ radiation here set at 1.5405 Å, B₄₂₂ is the FWHM value for the (422) reflection and θ is the Bragg angle i.e the incident angle.

The obtained FWHM from the measurement contains both broadening from the instrument and broadening caused by the small grain size. To compensate for this a gaussian approximation was used (Birkholz, 2006). B₄₂₂ is the line broadening (in radians) at FWHM after subtracting the instrumental broadening (0,00174533 radians) and is defined in equation (3):

$${B}_{422} = √ ( {( {FWHM}_{obs} )}^{2} - {( {FWHM}_{ins} )}^{2} ) \qquad ( 3 )$$

where B₄₂₂ is the broadening (in radians) used for the grain size calculation, FWHM_{obs} is the measured broadening (in radians), FWHMᵢₙₛ is the instrumental broadening (in radians).

### Grain Width Measurements Using Electron Backscatter Diffraction (EBSD)

The average grain width of the Ti(C,N) grains in the uppermost region of the Ti(C,N), T2, about 300 nm from the bonding layer, was herein determined by the average grain intercept (AGI) method which is a technique to quantify the grain width by drawing a line on the micrograph, counting the number of times the line intersects a grain boundary, and finding the ratio of intercepts to the line length.
AGI=(number of intercepts)/(line length).

In order to clearly determine the grain boundaries of the T2 portion, electron backscatter diffraction (EBSD) was performed on the coatings cross-section using a Zeiss Supra 55 equipped with Oxford Instruments Symmetry EBSD detector. The coating cross-sections were prepared for CNMG120408-PM inserts which were baked in a black conductive phenolic resin from AKASEL, ground down about 1 mm and polished in two steps: rough polishing (9 μm) and fine polishing (1 μm) using a diamond slurry solution followed by a final polishing using colloidal silica solution. After the final polishing step, the insert was removed from the conductive resin, cleaned in ethanol, nitrogen blow dried and mounted on a 70° pre-tilted holder for EBSD analysis. The microscope was operated at an acceleration voltage of 15 kV, a 1.6 nA beam current and a working distance of 13-15 mm. For the data acquisition, the detector was used at binning mode of 622×512 px for an area of at least 12 μm in width and 2 μm in height was analysed with a step size of 15 nm. A line was placed about 300 nm from the bonding layer in this area, the line being 12 μm long. Three separate measurements were made at different analysed areas of the sample to get an average value of the grain width, The Ti2CN, J Electrochem.Soc [JESOAN], (1950), vol 97, pg 299-304 crystallographic structural data was used as the reference for the Ti(C,N) phase and 44 reflectors were used for the measurements. The average grain width of the Ti(C,N) grains at the region of the portion T2 closest to the bonding layer was analysed by defining grain boundary misorientation of 10° and counting the number of intercepts between the boundaries along the defined drown line in an EBSD (Band Contrast) map using Aztec software version 3.0.

Orientation of the Lowermost Al₂O₃, Portion A1

The portion of the Al₂O₃ layer which is close to the bonding layer is in this invention very highly oriented. To analyse this area a cross section of the coating was prepared and the Al₂O₃ grains in the portion A1, extending 1 μm in height from the bonding layer, was studied in detail by EBSD. The preparation of the polished cross-sections was performed by mounting each of the CNMG120408-PM inserts in a black conductive phenolic resin from AKASEL which were afterwards ground down about 1 mm and then polished in two steps: rough polishing (9 μm) and fine polishing (1 μm) using a diamond slurry solution. A final polish using colloidal silica solution was applied.

The orientation of the lowermost portion of the Al₂O₃ is determined as the fraction in (%) of an analysed area that is within a certain angular deviation from a set axis. For portion A1 the <001> Al₂O₃ direction was chosen as the direction parallel to the surface normal. The orientation was calculated as the amount of analysed area that was ≤15° deviation from the set <001> Al₂O₃ direction.

Regions of at least 80 μm width were analysed with a step size of 50 nm, Speed 1 binning mode was used (622×512 px). To analyse the orientation of A1 four rectangular shaped sections of A1 were randomly chosen along the interface sized to 10 μm wide and 1 μm in height. The orientation was calculated as the average of the four rectangular shaped sections. One auto-clean up step and one zero solution removal using the 5 nearest neighbors' level was applied to the data. The Aztec Crystal software (v 2.0) was used for the determination of the orientation.

The orientation of the A1 portion was analysed using a Zeiss Supra 55 and a Helios Nanolab 650, both equipped with Oxford-symmetry EBSD detectors. 20 kV accelerating voltage and 13-26 nA beam current were used. The samples were mounted on a 70° pre-tilted sample holder to ensure maximum collection efficiency.

The Alumina (Alpha), Acta Crystallogr, Sec B [ACBCAR], vol 49B pp 973-980, reference was used for the Al₂O₃ measurements, 89 reflectors were used for the measurements.

### SEM Investigation

The SEM investigations of the polished cross sections and the sample top surfaces were carried out in a Carl Zeiss AG- Supra 40 type operated at 3 kV acceleration voltage using a 30 μm aperture size. The images were acquired using a secondary electron detector. The layer thicknesses were measured in the SEM images of the cross sections.

X-Ray Diffraction Measurement of Ti(C,N) and Al₂O₃

In order to investigate the texture of the layer(s) X-ray diffraction was conducted on the flank face of cutting tool inserts using a PANalytical CubiX3 diffractometer equipped with a PIXcel detector. The coated cutting tool inserts were mounted in sample holders to ensure that the flank face of the cutting tool inserts is parallel to the reference surface of the sample holder and also that the flank face was at appropriate height. Cu-Kα radiation was used for the measurements, with a voltage of 45 kV and a current of 40 mA. Anti-scatter slit of ½ degree and divergence slit of ¼ degree were used. The diffracted intensity from the coated cutting tool was measured in the range 20° to 140° 2θ, i.e. over an incident angle θ range from 10 to 70°.

The data analysis, including background subtraction, Cu-K_{α2} stripping and profile fitting of the data, was done using PANalytical's X'Pert HighScore Plus software. A general description of the fitting is made in the following. The output (integrated peak areas for the profile fitted curve) from this program was then used to calculate the texture coefficients of the layer by comparing the ratio of the measured intensity data to the standard intensity data according to a PDF-card of the specific layer (such as a layer of Ti(C,N) or α-Al₂O₃), using the Harris formula (2) as disclosed above. Since the layer is finitely thick the relative intensities of a pair of peaks at different 2θ angles are different than they are for bulk samples, due to the differences in path length through the layer. Therefore, thin film correction was applied to the extracted integrated peak area intensities for the profile fitted curve, taking into account also the linear absorption coefficient of the layer, when calculating the TC values. Since possible further layers above for example the α-Al₂O₃ layer will affect the X-ray intensities entering the α-Al₂O₃ layer and exiting the whole coating, corrections need to be made for these as well, taking into account the linear absorption coefficient for the respective compound in a layer. The same applies to X-ray diffraction measurements of a Ti(C,N) layer if the Ti(C,N) layer is located below for example an α-Al₂O₃ layer. Alternatively, a further layer, such as TiN, above an alumina layer can be removed by a method that does not substantially influence the XRD measurement results, e.g. chemical etching.

In order to investigate the texture of the α-Al₂O₃ layer X-ray diffraction was conducted using CuK_{α} radiation and texture coefficients TC (hkl) for different growth directions of the columnar grains of the α-Al₂O₃ layer were calculated according to Harris formula (2), where I(hkl)=measured (integrated area) intensity of the (hkl) reflection, I₀(hkl)=standard intensity according to ICDD's PDF-card no 00-010-0173, n=number of reflections to be used in the calculation. In this case the (hkl) reflections used are: (1 0 4), (1 1 0), (1 1 3), (0 2 4), (1 1 6), (2 1 4), (3 0 0) and (0 0 12). The measured integrated peak area is thin film corrected and corrected for any further layers above (i.e. on top of) the α-Al₂O₃ layer before said ratio is calculated.

The texture coefficients TC (hkl) for different growth directions of the columnar grains of the Ti(C,N) layer were calculated according to Harris formula (2) as disclosed earlier, where I(hkl) is the measured (integrated area) intensity of the (hkl) reflection, I₀(hkl) is the standard intensity according to ICDD's PDF-card no 42-1489, n is the number of reflections to be used in the calculation. In this case the (hkl) reflections used are (1 1 1), (2 0 0), (2 2 0), (3 1 1), (3 3 1), (4 2 0) and (4 2 2).

It is to be noted that peak overlap is a phenomenon that can occur in X-ray diffraction analysis of coatings comprising for example several crystalline layers and/or that are deposited on a substrate comprising crystalline phases, and this has to be considered and compensated for. An overlap of peaks from the α-Al₂O₃ layer with peaks from the Ti(C,N) layer might influence measurement and needs to be considered. It is also to be noted that for example, WC in the substrate can have diffraction peaks close to the relevant peaks of the present invention.

### BRIEF DESCRIPTION OF DRAWINGS

Embodiments of the invention will be described with reference to the accompanying drawings, wherein:

FIG. 1 shows a Scanning Electron Microscope (SEM) image of a cross section of an example of the inventive coating, Sample 090, where the portions T1 and T2 of the Ti(C,N) layer, the bonding layer (B), the substrate (S) and the portion A1 of the α-Al₂O₃ layer are indicated,

FIG. 2 shows a close up image of the T2 portion of the sample shown in FIG. 1,

FIG. 3 shows a Scanning Electron Microscope (SEM) image of a cross section of an example of the inventive coating, Sample 045,

FIG. 4 shows a close up image of the T2 portion of the sample showed in FIG. 3,

FIG. 5 shows a Scanning Electron Microscope (SEM) image of a cross section of a reference sample, Ref 0,

FIG. 6 shows a close up image of the outer portion of the Ti(C,N) layer of the sample showed in FIG. 5,

FIG. 7 shows a Scanning Electron Microscope (SEM) image of a cross section of a reference sample, sample Ref260,

FIG. 8 shows a close up image of the outer portion of the Ti(C,N) layer of the sample showed in FIG. 7.

FIG. 9 shows a forescattered image of a cross section of an example of the inventive coating, sample 130, acquired from center low forward scatter detector (FSD) on the EBSD camera providing orientation contrast and revealing the grain structure on the Ti(C,N) layer, where the portions T1 and T2 of the Ti(C,N) layer, the bonding layer (B), the substrate (S) and the portion A1 of the α-Al₂O₃ layer are indicated,

FIG. 10 shows an EBSD-band contrast image of sample 130 revealing grain structure wherein dark areas correspond to low and right areas to high band contrast values,

FIG. 11 shows a carbon mapping from EPMA of sample 090, where the portions T1 and T2 of the Ti(C,N) layer, the bonding layer (B), the substrate (S) and the portion A1 of the α-Al₂O₃ layer are indicated,

FIG. 12 shows a nitrogen mapping from EPMA of sample 090,

FIG. 13 shows a carbon mapping from EPMA of sample 130,

FIG. 14 shows a nitrogen mapping of sample 130, and

FIG. 15 shows a schematic view of one embodiment of a cutting tool (1) having a rake face (2) and flank faces (3) and a cutting edge therebetween.

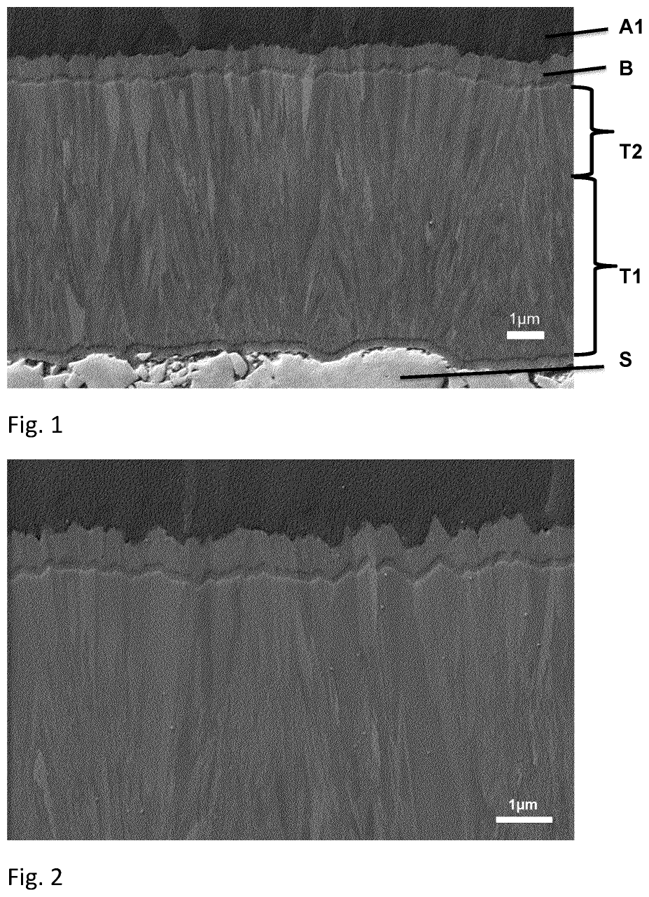

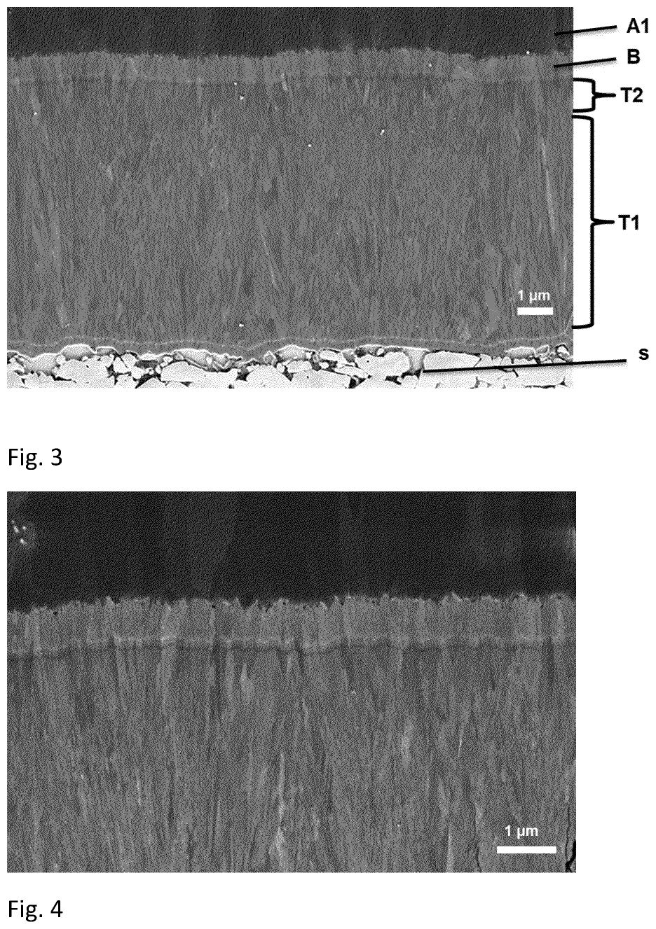

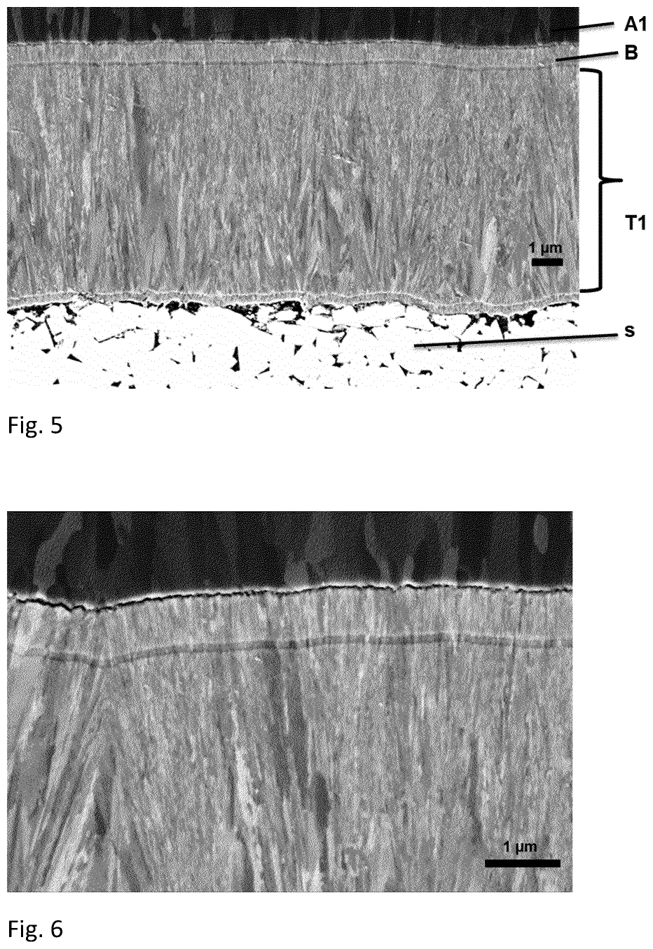

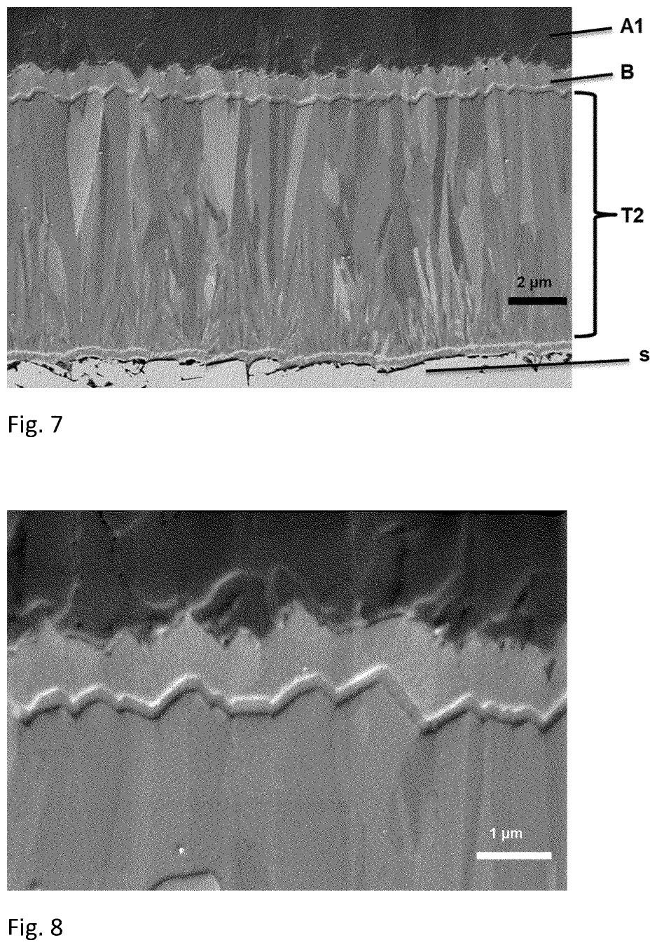

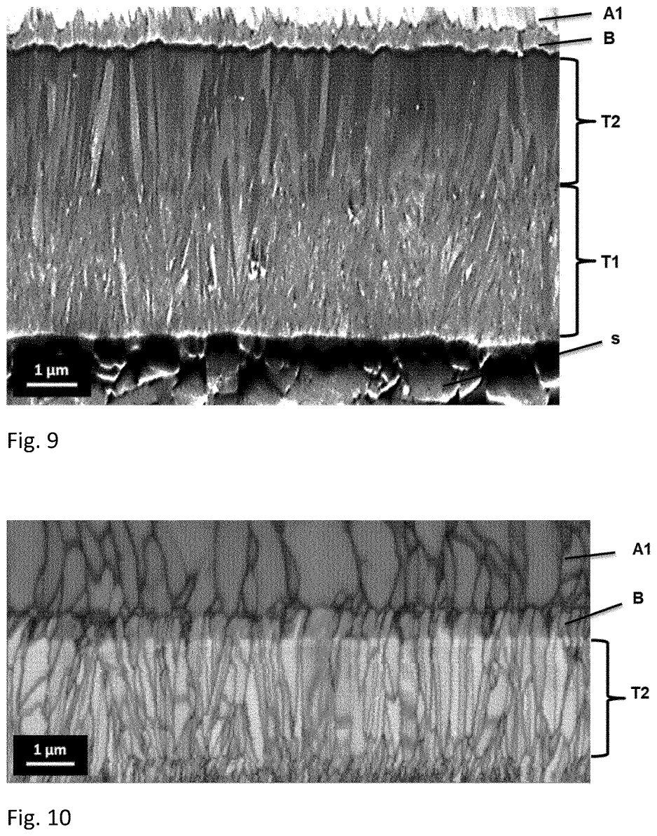

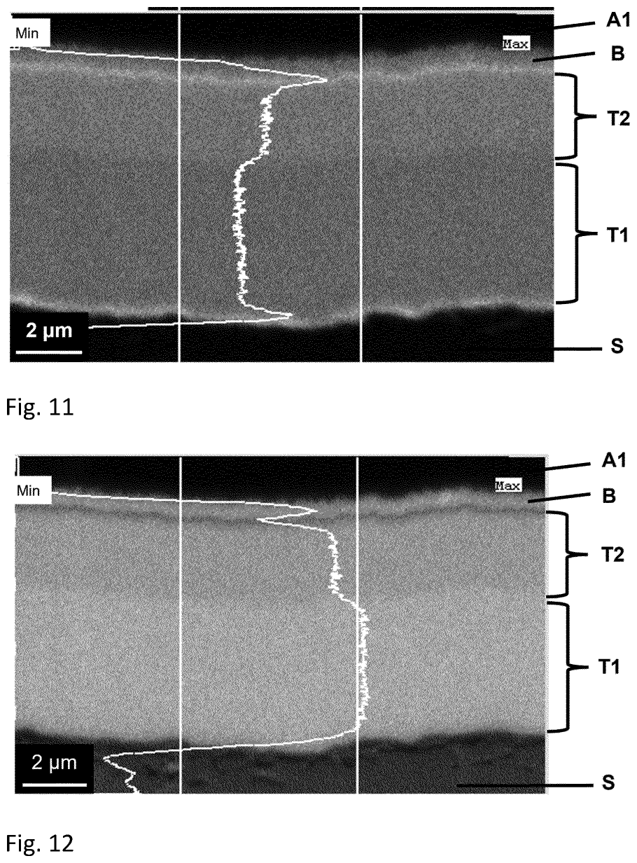

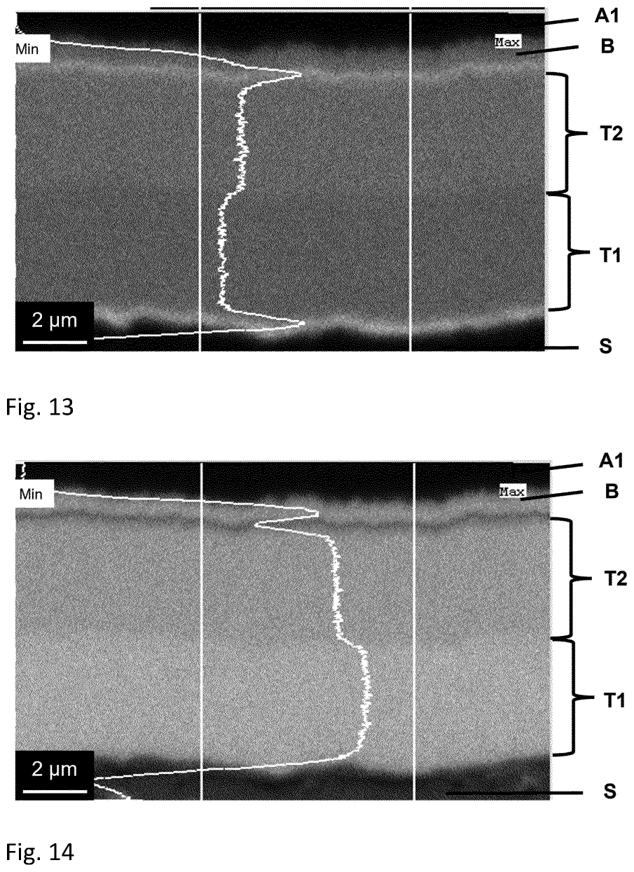

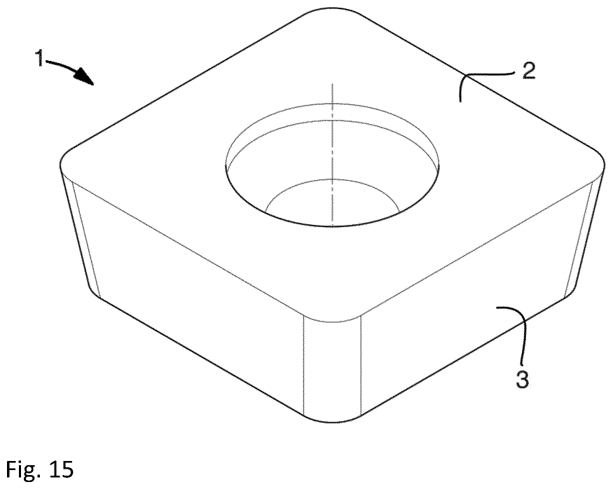

### EXAMPLES

Exemplifying embodiments of the present invention will now be disclosed in more detail and compared to reference embodiments. Coated cutting tools were manufactured, analysed and tested in metal cutting tests.

### Substrates

Cemented carbide substrates were manufactured utilizing conventional processes including milling, mixing, spray drying, pressing and sintering. The ISO-type geometry of the cemented carbide substrates (inserts) was CNMG-120408-PM. The composition of the cemented carbide was 7.2 wt % Co, 2.9 wt % TaC, 0.5 wt % NbC, 1.9 wt % TiC, 0.4 wt % TiN and the rest WC.

Before the coating depositions the substrates were exposed to a mild blasting treatment to remove any residuals on the substrate surfaces from the sintering process.

### CVD Deposition

The sintered substrates were CVD coated in a radial CVD reactor of Bernex Type size 530 capable of housing 10.000 half inch size cutting inserts. The samples to be tested and analysed further were selected from the middle of the chamber and at a position along half the radius of the plate between the center and the periphery of the plate. Mass flow controllers is to be chosen so that the flow rate of for example CH₃CN is selected to allow the flow rates in the CVD recipe.

A first innermost coating of about 0.3 μm TiN was deposited on all substrates using a deposition temperature of 885° C. and a pressure of 400 mbar. A gas mixture of 48.8 vol % H₂, 48.8 vol % N₂ and 2.4 vol % TiCl₄ was used.

Thereafter followed the Ti(C,N) layer deposition, and all samples were deposited with different Ti(C,N) receipts in accordance with the following. The reference sample Ref260 was deposited with the process step V followed by process step W as shown in Table 1. The Ti(C,N) layer of reference sample Ref0 was deposited with the process step X as shown in Table 1. On samples 015, 020, 030, 045, 090, 130 the Ti(C,N) layers were deposited with the process step X followed by process step Z using the deposition times as indicated in Tables 1 and 2. The temperature adjustment from 885° C. to 870° C. was made in 50 vol % H₂ and 50 vol % N₂ at 80 mbar before starting with process step X for the relevant samples. The layer thicknesses of the samples are presented in table 4.

TABLE 1

| | Process | Process | Process | Process |
|---|---|---|---|---|
| Parameter | step X | step Z | step V | step W |
| H₂ | Balance | Balance | Balance | Balance |
| N₂ | | 7.76% | 37.57% | 7.76% |
| TiCl₄ | 2.95% | 2.38% | 2.95% | 2.38% |
| CH₃CN | 0.45% | 0.65% | 0.45% | 0.65% |
| HCl | | 7.76% | | 7.76% |
| Total gas flow | 5600 | 7734 | 5590 | 7734 |
| [std l/h] | | | | |
| Pressure | 80 | 70 | 55 | 55 |
| [mbar] | | | | |
| Temperature | 870 | 870 | 885 | 885 |
| [° C.] | | | | |

| | | | |
|---|---|---|---|
| Process time | See Table 2 | 10 | 260 |
| [min] | | | |

TABLE 2

| | Process step X | Process step Z |
|---|---|---|
| Sample | [minutes] | [minutes] |
| Ref0 | 260 | — |
| 015 | 245 | 15 |
| 020 | 240 | 20 |
| 030 | 230 | 30 |
| 045 | 215 | 45 |
| 090 | 170 | 90 |
| 130 | 130 | 130 |

A 0.7-1.1 μm thick bonding layer was deposited at 1000° C. on top of the Ti(C,N) layer by a process consisting of four separate reaction steps. First a 8 minutes HTCVD Ti(C,N) step using TiCl₄, OH₄, N₂, HCl and H₂ at 400 mbar, then a second step (Ti(C,N,O)-1) using TiCl₄, CH₃CN, CO, N₂ and H₂ at 70 mbar for 7 minutes, then a third step (Ti(C,N,O)-2) using TiCl₄, CH₃CN, CO, N₂ and H₂ at 70 mbar for 5 minutes and finally a fourth step (TiN) using TiCl₄, N₂ and H₂ at 70 mbar for 6 minutes. During the third deposition step the CO gas flow was continuously linearly increased from a start value at the beginning of the process step to a stop value at the end of the process step as shown in Table 3. All other gas flows were kept constant, but since the overall gas flow is increased, the concentration of all gases was somewhat influenced due to this. Prior to the start of the subsequent Al₂O₃ nucleation, the bonding layer was oxidized for 4 minutes in a mixture of CO₂, CO, N₂ and H₂.

The details of the bonding layer deposition are shown in Table 3.

TABLE 3
Bonding layer deposition

| Bonding | Pressure | H₂ | N₂ | CH₄ | HCl | CO | TiCl₄ | CH₃CN | CO₂ |
|---|---|---|---|---|---|---|---|---|---|
| layer | [mbar] | [vol %] | [vol %] | [vol %] | [vol %] | [vol %] | [vol %] | [vol %] | [vol %] |
| Temp. | 55 | Balance | 25 | | | | | | |
| increase | | | | | | | | | |
| HTCVD | 400 | Balance | 25.5 | 3.4 | 1.7 | — | 1.55 | — | — |
| Ti(C, N) | | | | | | | | | |
| Ti(C, N, O)-1 | 70 | Balance | 12.0 | — | 1.2 | 1.2 | 1.5 | 0.40 | — |
| Ti(C, N, O)-2 | 70 | Balance | 31.5-30.6 | — | — | 1.6-4.6 | 3.15-3.06 | 0.65-0.63 | — |
| TiN | 70 | Balance | 32.3 | — | — | — | 3.23 | — | — |
| Oxidation | 55 | Balance | 30 | — | — | 12.5 | — | — | 3.7 |

On top of the bonding layer an α-Al₂O₃ layer was deposited. All the α-Al₂O₃ layers were deposited at 1000° C. and 55 mbar in two steps. The first step using 1.2 vol-% AlCl₃, 4.7 vol-% CO₂, 1.8 vol-% HCl and balance H₂ was run for 30 minutes giving about 0.1 μm α-Al₂O₃. The process time of the second step was adjusted to give a total α-Al₂O₃ layer thickness of about 5 μm. The second step of the α-Al₂O₃ layer was deposited using 1.16% AlCl₃, 4.65% CO₂, 2.91% HCl, 0.58% H₂S and balance H₂.

### Coating Analysis Results

The layer thicknesses were measured on the rake face of the cutting tool samples using a Scanning Electron Microscope. The layer thicknesses of the samples are shown in Table 4.

TABLE 4
Layer thickness from SEM measurement

| | | Ti(C, N) | Bonding layer | Alumina |
|---|---|---|---|---|
| Sample | TiN [μm] | [μm] | [μm] | [μm] |
| Ref0 | 0.31 | 7.49 | 0.72 | 4.74 |
| 015 | 0.31 | 7.28 | 0.81 | 4.78 |
| 020 | 0.32 | 8.08 | 0.79 | 4.87 |
| 030 | 0.31 | 7.30 | 0.78 | 5.13 |
| 045 | 0.31 | 7.45 | 0.78 | 5.06 |
| 090 | 0.29 | 7.51 | 0.78 | 5.24 |
| 130 | 0.34 | 7.70 | 0.94 | 5.33 |
| Ref260 | 0.36 | 8.22 | 1.08 | 5.46 |

The thickness of the inner portion T1 and the outer portion T2 was measured in the cross section by utilizing both the line scan and element mapping in the EPMA and the SEM. It can be noted that the bonding layer of the samples includes a HT-Ti(C,N) sublayer that is very common in the technical area of Ti(C,N) and α-Al₂O₃ coated cutting tools and that this HT-Ti(C,N) sublayer is very nitrogen rich.

The average grain size measurement was performed on the Ref0 sample with XRD using Scherrer equation and the average grain size of T1 in all samples was thereby concluded to be about 30 nm.

The average grain width of the Ti(C,N) grains in the portion T2 of the Ti(C,N) layer was measured using the method disclosed in the method section above. The results are presented in Table 5.

C and N content measurement was made in accordance with the above method. The atomic percentage of the elements was used in the ratio calculation.

TABLE 5
Values of the portions in the Ti(C, N) layer

| | Thickness of | Thickness of | Total | Average | Ratio of | Ratio of |
|---|---|---|---|---|---|---|
| | inner portion | outer portion | Ti(C, N) | grain | atom % | atom % |
| | T1 of | T2 of | thickness | width in T2 | C/N in T1 | C/N in T2 |
| Sample | Ti(C, N) [μm] | Ti(C, N) [μm] | [μm] | portion [nm] | portion | portion |
| Ref0 | 7.49 | No T2 | 7.49 | No T2 | 1.56 | No T2 |
| | | portion | | portion | | portion |
| 030 | 6.55 | 0.75 | 7.30 | 109 | n.a. | n.a. |
| 045 | 6.18 | 1.27 | 7.45 | 103 | 1.57 | 1.34 |
| 090 | 5.04 | 2.47 | 7.51 | 193 | 1.54 | 1.31 |
| 130 | 4.12 | 3.58 | 7.70 | 187 | 1.52 | 1.29 |
| Ref260 | No T1 | 8.22 | 8.22 | 491 | No T1 | 1.30 |
| | portion | | | | portion | |

Texture coefficients of the Ti(C,N) and the α-Al₂O₃ layers were analysed using X-ray diffraction and the results are presented in Table 6.

EBSD of inner alumina, A1, measurement was performed. The orientation of the α-Al₂O₃ grains in the inner portion, A1, of the α-Al₂O₃ layer was analysed. The results are presented in Table 6.

TABLE 6
Orientation of the layers

| | | | | Orientation in |
|---|---|---|---|---|
| | | TC(422) + | | portion A1 of |
| | TC(422) of | TC(311) of | TC(0012) of | α-Al₂O₃ |
| | Ti(C, N) | Ti(C, N) | α-Al₂O₃ | layer, ≤15% from |
| Sample | layer | layer | layer | <001> [%] |
| Ref0 | 3.96 | 5.52 | 7.99 | 94.8% |
| 015 | 3.84 | 5.32 | 7.96 | 96.6% |
| 020 | 4.26 | 5.81 | 7.97 | 97.2% |
| 030 | 4.34 | 5.78 | 7.96 | 98.6% |
| 045 | 4.01 | 5.63 | 7.95 | 97.9% |
| 090 | 3.42 | 5.13 | 7.89 | 81.1% |
| 130 | 3.40 | 5.15 | 7.83 | 72.2% |
| Ref260 | 3.81 | 5.77 | 7.59 | 60.1% |

### Performance Testing

The cutting tools were first evaluated by being exposed to an abrasive wet blasting. The blasting was performed on the rake faces of the cutting tools. The blaster slurry consisted of 20 vol-% alumina in water and an angle of 90° between the rake face of the cutting insert and the direction of the blaster slurry. The distance between the gun nozzle and the surface of the insert was about 145 mm. The pressure of the slurry to the gun was 1.8 bar for all samples, while the pressure of air to the gun was 2.2 bar. The alumina grits were F230 mesh (FEPA 42-2:2006). The average time for blasting per area unit was 4.4 seconds. Sample Ref0 could not withstand the wet blasting, the coating of samples 015 and 020 showed severe flaking. All the other samples 030, 045, 090 and 130 and Ref260 did withstand the wet blasting with no flaking of the coatings.

The as coated cutting tools were also tested in a face turning operation (from dia. 180 mm to dia. 60 mm) in a work piece material DIN C45E, a medium carbon and alloyed steel. The spindle speed was fixed in n=120 rpm; thus, the cutting speed constantly varied from, Vc, ˜70 m/min (at dia. 180 mm) to Vc, ˜20 m/min (at dia. 60 mm) along the face turning operation; the feed, fn, was constantly increased from 0.1 mm/revolution (at dia. 180 mm), to 0.5 mm/revolution (at dia. 60 mm) along the face turning operation; the depth of cut was 2 mm and no cutting fluid was used. Four samples of each variant were used in this test.

In order to measure the total area of the exposed Ti(C,N) on the rake face after the face turning operation, the inserts were etched for 15 min in a HCl (Hydrochloric acid) solution. In the sequence, SEM investigations of the top surface were carried out using a Zeiss AG-Supra 40 type operated at 10 kV acceleration voltage using a 30 μm aperture size. Images were acquired at 50× magnification using a backscatter electron detector. Images were later used to measure the area of coating ripped out using an image analysis software, where a larger measured area corresponds to more wear due to less adhesion of the α-Al₂O₃ layer.

The as coated cutting tools were further tested in a longitudinal turning operation in a workpiece material Ovako 825B (100CrMo7-3), a high alloyed steel. The cutting speed, Vc, was 220 m/min, the feed, fn, was 0.3 mm/revolution, the depth of cut was 2 mm and water miscible cutting fluid was used. The machining was continued for 14 minutes and thereafter the wear of the cutting tools was evaluated. One cutting edge per cutting tool was evaluated.

The wear of the cutting tools after the longitudinal cutting test was evaluated. In order to measure the total area of the exposed Ti(C,N) on the rake face, SEM investigations of the top surface were carried out using an Zeiss AG- Supra 40 type operated at 10 kV acceleration voltage using a 30 μm aperture size. Several images were acquired at 250× magnification using a backscatter electron detector. Images were later used to measure the area of exposed Ti(C,N) using an image analysis software, where a larger measured area corresponds to more wear.

The wear after the longitudinal turning operation was also studied via cross sections of the crater area. An FEI Helios FIB/SEM instrument was used to produce controlled cross-sections on the rake face and parallel to the chip flow direction. The cross-sections were produced at the exact location of 550 μm from the primary edge and 320 μm from the secondary edge with a length of 150 μm and depth of around 18 μm so that the whole coating and part of the substrate are visible. In order to protect the surface from ion beam damage, a thin Pt layer with a thickness of around 100 nm was first deposited onto the surface (150 μm long and 3.5 μm wide) using the electron beam and then a thicker Pt layer (˜3 μm) was deposited on top with the assistance of Ga-ions. Cross-sections were produced in two steps, rough ion milling using a regular cross-section pattern with 47 nA ion beam followed by a fine ion milling using a cleaning cross-section pattern with 9.2 nA. Utilizing image analysis software, the cross-sections were afterward used to measure the area of Ti(C,N) layer, where a greater Ti(C,N) layer area translates to less wear.

The result of the cutting test is presented in Table 7.

TABLE 7
Performance results

| | | Adhesion | | |
|---|---|---|---|---|
| | | Coating ripped | Crater area | FIB cut- |
| | Blasting, | out area | (Exposed | Ti(C, N) |
| | coating | (Al₂O₃ + Ti(C, N)) | Ti(C, N)) | area |
| Sample | response | [mm²] | [μm²] | [μm²] |
| Ref0 | Total flaking | 2.65 | n.a. | n.a. |
| 015 | Severe flaking | n.a. | n.a. | n.a. |
| 020 | Severe flaking | 2.38 | n.a. | n.a. |
| 030 | No flaking | 0.24 | 2 870 | 760 |
| 045 | No flaking | 0.17 | 4 540 | 740 |
| 090 | No flaking | 0.12 | 5 550 | 660 |
| 130 | No flaking | 0.16 | 10 120 | 650 |
| Ref260 | No flaking | 0.20 | 20 670 | 600 |

(n.a. = not analysed)

As can be seen in the Table 7 all the samples 030, 045, 090 and 130 showed higher resistance to crater wear as compared to the Ref260 reference sample.

While the invention has been described in connection with various exemplary embodiments, it is to be understood that the invention is not to be limited to the disclosed exemplary embodiments; on the contrary, it is intended to cover various modifications and equivalent arrangements within the appended claims.

1. A coated cutting tool comprising a substrate at least partially coated with a coating, the coating comprising a layer of Ti(C,N), a layer of α-Al₂O₃ and therebetween a bonding layer, wherein the Ti(C,N) layer has a thickness of 3-20 μm, and is composed of columnar grains, wherein the Ti(C,N) layer includes n inner Ti(C,N) portion, T1, followed by an outer Ti(C,N) portion, T2, as seen in a direction from the substrate towards a outer surface of the tool, a thickness of the inner portion, T1, being 2.5-15 μm, and a thickness of the outer portion, T2, being 0.5-5 μm, wherein an average grain width of the Ti(C,N) grains in the inner Ti(C,N) portion, T1, is smaller than 300 nm, and an average grain width of the Ti(C,N) grains in the outer Ti(C,N) portion, T2, is smaller than 300 nm, wherein an atomic ratio C/N in the inner Ti(C,N) portion, T1, is 1.50-1.60, and wherein an atomic ratio C/N in the outer Ti(C,N) portion, T2, is 1.25-1.40.

2. The coated cutting tool of claim 1, wherein the average grain width of the Ti(C,N) grains in the inner Ti(C,N) portion, T1, is smaller than the average grain width of the Ti(C,N) in the outer Ti(C,N) portion, T2.

3. The coated cutting tool of claim 1, wherein the Ti(C,N) layer includes an outer portion, T2, which is adjacent to the bonding layer, and wherein in the Ti(C,N) grains in an uppermost region of the outer Ti(C,N) portion, T2, has an average grain width of 90-250 nm.

4. The coated cutting tool of claim 1, wherein the average grain width of the Ti(C,N) grains in the inner Ti(C,N) portion, T1, is <100 nm.

5. The coated cutting tool of claim 1, wherein an average grain size D₄₂₂ of the inner Ti(C,N) portion, T1, of the Ti(C,N) layer is 25-50 nm, as measured with X-ray diffraction with CuKα radiation, the grain size D₄₂₂ being calculated from a full width at half maximum (FWHM) of the (422) peak according to Scherrer's equation:
$${D}_{422} = \frac{K λ}{{B}_{422} cos θ} \qquad ( 1 )$$
wherein D₄₂₂ is the average grain size of the Ti(C,N), K is the shape factor here set at 0.9, λ, is the wavelength for the CuKα radiation here set at 1.5405 Å, B₄₂₂ is the FWHM value for the (422) reflection and θ is the Bragg angle.

6. The coated cutting tool of claim 1, wherein a thickness of the α-Al₂O₃ layer is 1-15 μm.

7. The coated cutting tool of claim 1, wherein the α-Al₂O₃ layer exhibits a texture coefficient TC(hkl), as measured by X-ray diffraction using CuKα radiation and θ-2θ scan, defined according to Harris formula
$$TC ( hkl ) = {\frac{I ( hkl )}{{I}_{0} ( hkl )} [ \frac{1}{n} {\sum }_{n = 1}^{n} \frac{I ( hkl )}{{I}_{0} ( hkl )} ]}^{- 1} \qquad ( 2 )$$
where I(hkl) is the measured intensity (integrated area) of the (hkl) reflection, I₀(hkl) is the standard intensity according to ICDD's PDF-card No 00-010-0173, n=number of reflections, the reflections used are: (1 0 4), (1 1 0), (1 1 3), (0 2 4), (1 1 6), (2 1 4), (3 0 0) and (0 0 12), wherein the TC(0 0 12) is the largest texture coefficient.

8. The coated cutting tool of claim 1, wherein TC(0012) of the α-Al₂O₃ layer is >7.7.

9. The coated cutting tool of claim 1, wherein the α-Al₂O₃ layer includes a portion A1 extending 1 μm from the bonding layer, wherein the portion A1 is measured with Electron Backscatter Diffraction (EBSD) on a cross section of the α-Al₂O₃ layer, wherein a surface normal of the α-Al₂O₃ layer is parallel to the surface normal of the substrate surface, and wherein the portion A1 exhibits an orientation wherein ≥70%, of the analysed area has a <001> direction within 15 degrees from the surface normal of the α-Al₂O₃ layer.

10. The coated cutting tool of claim 1, wherein the Ti(C,N) layer exhibits a texture coefficient TC(hkl), as measured by X-ray diffraction using CuKα radiation and θ-2θ scan, defined according to Harris formula (2), where I(hkl) is the measured intensity (integrated area) of the (hkl) reflection, I₀(hkl) is the standard intensity according to ICDD's PDF-card No 42-1489, n is the number of reflections, reflections used in the calculation are (1 1 1), (2 0 0), (2 2 0), (3 1 1), (3 3 1), (4 2 0) and (4 2 2), wherein TC(422)>3.

11. The coated cutting tool of claim 1, wherein TC(422)+TC(311) of the Ti(C,N) layer is 5-6.

12. The coated cutting tool of claim 1, wherein the bonding layer includes at least one compound selected from the group of titanium carboxide, titanium oxynitride and titanium carboxynitride, and wherein a thickness of the bonding layer is 0.5-2 μm.

13. The coated cutting tool of claim 1, wherein the coating includes an innermost layer of TiN with a thickness of 0.1-0.5 μm.

14. The coated cutting tool of claim 1, wherein the substrate of the coated cutting tool is selected from the group of cemented carbide and cermet.
